(19) United States
(12) Patent Application Publication
(10) Pub. No.: US 2003/0227334 A1
(43) Pub. Date: Dec. 11, 2003

(54) Self-adjusting oscillator for a USB connectivity interface

(76) Inventors: Pei-Sung Chuang, Taipei Hsien (TW); Ming-Te Tseng, Chung-Ho City (TW); Kuan-Chia Huang, Lu-Chou City (TW)

Correspondence Address: Alcor Micro, Corp., P.O. Box No.6-57, Chung-Ho, Taipei, 235, TW

(21) Appl. No.: 10/163,515

(22) Filed: Jun. 7, 2002

(51) Int. Cl. H03B 1/00

(52) U.S. Cl. 331/74

(57) ABSTRACT

A self-adjusting oscillator for a universal-serial-bus (USB) connectivity interface includes at least a voltage controlled oscillator for generating USB synchronous frequency required by a USB connectivity interface and at least a frequency feedback calculating and adjusting unit for capturing synchronous signals, receiving the feedback of the USB synchronous frequency generated by the voltage controlled oscillator and calculating the ratio value of the feedback; the ratio value determines whether the synchronous frequency generated by the voltage controlled oscillator is too fast or too slow such that a frequency adjusting signal is transmitted to the voltage controlled oscillator to form a self-adjusting synchronous oscillator with non-quartz oscillating frequency.

### BACKGROUND OF THE INVENTION

1) Field of the Invention

The present invention relates to a self-adjusting oscillator for a universal-serial-bus (USB) connectivity interface, more especially to a self-adjusting oscillator generating synchronous signals a USB connectivity interface and formed by non-quartz oscillating frequency.

2) Description of the Prior Art

Accordingly, universal-serial-bus (USB) connectors have been extensively used for connecting a USB interface circuit; a USB adapter connect a USB signal with a USB interface circuit to transmit the USB signal to the electronic equipment connected with the USB interface circuit. However, during the connecting and transmitting procedure between the USB interface circuit of the electronic equipment and the USB signal, the circuit or the control action inside the USB electronic equipment must have a synchronous transmission with the USB signal. Therefore, it is necessary to add a synchronous oscillator in the USB interface circuit for generating synchronous frequency thereby assuring the synchronous transmission and action of the circuit signal.

As indicated in FIG. 4, the synchronous oscillator of a conventional USB connectivity interface utilizes a D+ data line and a D− data line during the USB signal transmission procedure to generate a set of fixed synchronous signals (D1, D2) at a certain interval time period (referring to the regulation description of USB V1.1). The captured signals cooperate with a quartz oscillating element and an oscillating circuit to generate synchronous frequency. However, when connecting with a USB connectivity interface, the quartz oscillating circuit assembled by the quartz oscillating element fails to meet the requirements of the economical cost and industrial utilization value of the circuit application not only because the cost of the entire quartz oscillating circuit is considerably higher due to the high cost of the quartz oscillating element and complicated circuit design, but also because the quartz oscillating element generates natural frequency which is subjected to noise thereby causing the electromagnetic interference in the USB connector of the USB connectivity interface and affecting the quality and steadiness of the connection and transmission between the USB connectivity interface circuit and the signals.

### SUMMARY OF THE INVENTION

The primary objective of the present invention is to provide a self-adjusting oscillator for a universal-serial-bus (USB) connectivity interface comprising a voltage controlled oscillator and a frequency feedback calculating and adjusting unit through non-quartz oscillating element and quartz oscillating frequency to generate a synchronous frequency for the USB connectivity interface so as to lower the circuit cost.

Another objective of the present invention is to provide a self-adjusting oscillator for a USB connectivity interface, wherein the feedback of the voltage controlled oscillator generates the synchronous frequency to the frequency feedback calculating and adjusting unit thereby forming a closed loop system for feedback controlling so as to lower the electromagnetic noise in the connection and transmission between the USB connectivity interface and USB signals.

In order to achieve the abovementioned objectives, the present invention of a self-adjusting oscillator for a USB connectivity interface comprises at least a voltage controlled oscillator for generating USB synchronous frequency required by a USB connectivity interface and at least a frequency feedback calculating and adjusting unit for capturing USB synchronous signals in the USB connectivity interface, receiving the feedback of the USB synchronous frequency generated by the voltage controlled oscillator and calculating the ratio value of the feedback between the USB synchronous frequency and the captured USB synchronous signals; the ratio value determines whether the synchronous frequency generated by the voltage controlled oscillator is too fast or too slow thereby a frequency adjusting signal is transmitted to the voltage controlled oscillator to properly adjust the USB synchronous signal transmitted by the voltage controlled oscillator allowing the voltage controlled oscillator to use a non-quartz oscillating method to transmit USB synchronous frequency.

To enable a further understanding of the detail structure and the practical operation of the present invention, the brief description of the drawings below is followed by the detailed description of the preferred embodiment.

### BRIEF DESCRIPTION OF THE DRAWINGS

FIG. 1 is a block diagram of the circuit of the present invention.

FIG. 2 is a flow chart of the system action of the present invention.

FIG. 3 is a response oscillogram of the present invention of a voltage controlled oscillator transmitting a synchronous frequency.

FIG. 4 is an oscillogram of a synchronous signal on the data line of a conventional USB connectivity interface.

### DETAILED DESCRIPTION OF THE PREFERRED EMBODIMENTS

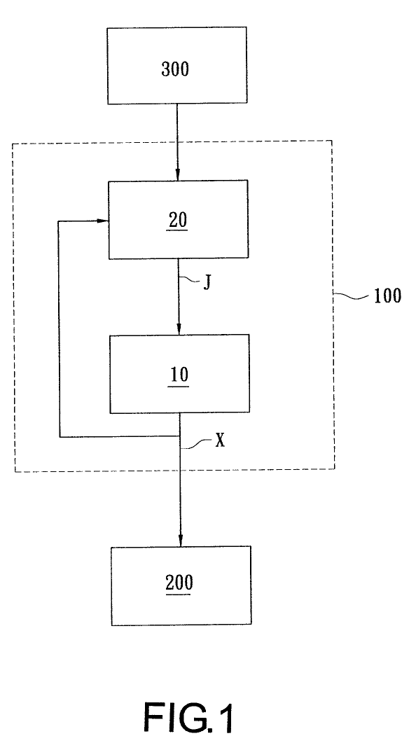

FIG. 1 shows the block diagram of the circuit of the present invention, wherein the self-adjusting oscillator (100) comprises at least a voltage controlled oscillator (10) and a frequency feedback calculating and adjusting unit (20); the voltage controlled oscillator (10) generates a universal-serial-bus (USB) synchronously oscillating signal (X) which has the ultimately preferred synchronous frequency. Furthermore, the USB synchronously oscillating signal (X) provides a USB electronic equipment (200) a base signal with synchronous frequency for circuit action or controlling; the USB electronic equipment (200) is a computer peripheral equipment, such as a USB printer or a USB modem.

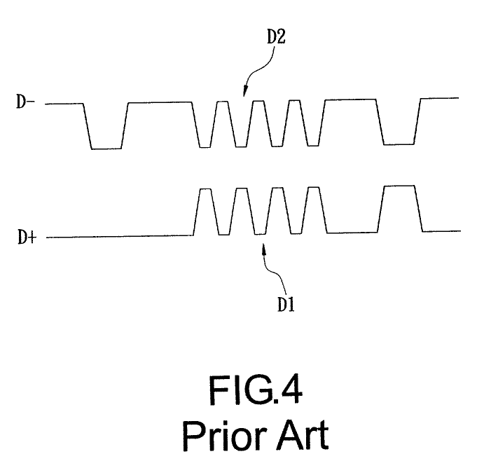

The USB synchronously oscillating signal (X) generated by the voltage controlled oscillator (10) sends feedback to the frequency feedback calculating and adjusting unit (20) for receiving the feedback of the synchronous frequency. The type of the frequency feedback calculating and adjusting unit (20) is not limited and it can be formed by a microprocessor or an equivalent circuit; it not only receives the synchronous frequency feedback of the voltage controlled oscillator (10), but also connects with a USB connectivity interface (300) for capturing synchronous signals (D1, D2) from a USB D+ data line and a D− data line, as shown in FIG. 4, as well as calculates the ratio value between the synchronous signals (D1, D2) and said synchronous frequency; based on the ratio value, a frequency adjusting signal (J) is transmitted to adjust the speed of the synchronous frequency generated by the voltage controlled oscillator (10) so as to reach the targeted frequency range to be controlled. The related adjusting and operation steps of the synchronous frequency will be described in detail in the later text.

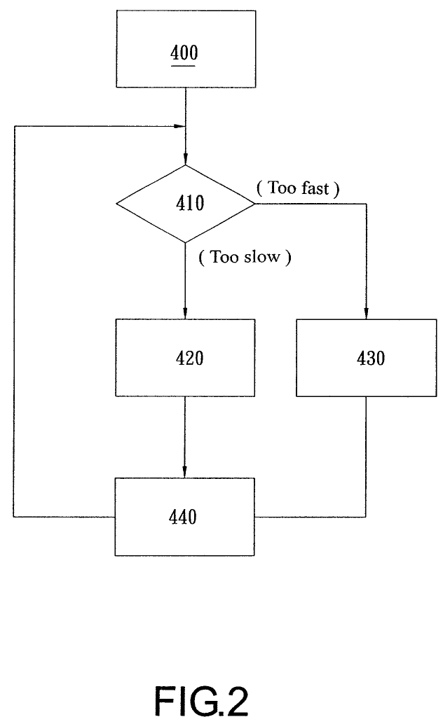

FIG. 2 shows the flow chart of the action steps (400-440) of the self-adjusting oscillator (100) of the present invention, wherein the step (400) captures the synchronous frequency signals (D1, D2), as shown in FIG. 4., through the connection between the frequency feedback calculating and adjusting unit (20) and the USB connectivity interface (300).

The step (410) calculates and determines the ratio value between the feedback frequency and the synchronous signal; that means, the frequency feedback calculating and adjusting unit (20) calculates the ratio value between the synchronous signals (D1, D2) captured by the step (400) and the synchronous frequency transmitted by the voltage controlled oscillator (10); the ratio value determines whether the synchronous frequency is too fast or too slow; if it is too slow, the step (420) takes action; if too fast, the step (430) starts.

The step (420) generates an accelerated frequency adjusting signal; that means, if the feedback synchronous frequency is calculated and determined by the frequency feedback calculating and adjusting unit (20) as too slow, the frequency feedback calculating and adjusting unit (20) transmits the accelerated frequency adjusting signal (J) to the voltage controlled oscillator (10).

The step (430) generates a decelerated frequency adjusting signal; that means, if the feedback synchronous frequency is calculated and determined by the frequency feedback calculating and adjusting unit (20) as too fast, the frequency feedback calculating and adjusting unit (20) transmits the decelerated frequency adjusting signal (J) to the voltage controlled oscillator (10).

The step (440) uses the voltage controlled oscillator (10) to generate synchronous frequency.

The flow chart of the action of the self-adjusting oscillator (100) of the present invention is only one of the exemplary embodiments and merely for the purpose of illustrating the operation steps in the technical content of the present invention. Any flow chart showing equivalent operation focused on the voltage controlled oscillator (10) and the frequency feedback calculating and adjusting unit (20) of the present invention should not depart from the scope of the present invention.

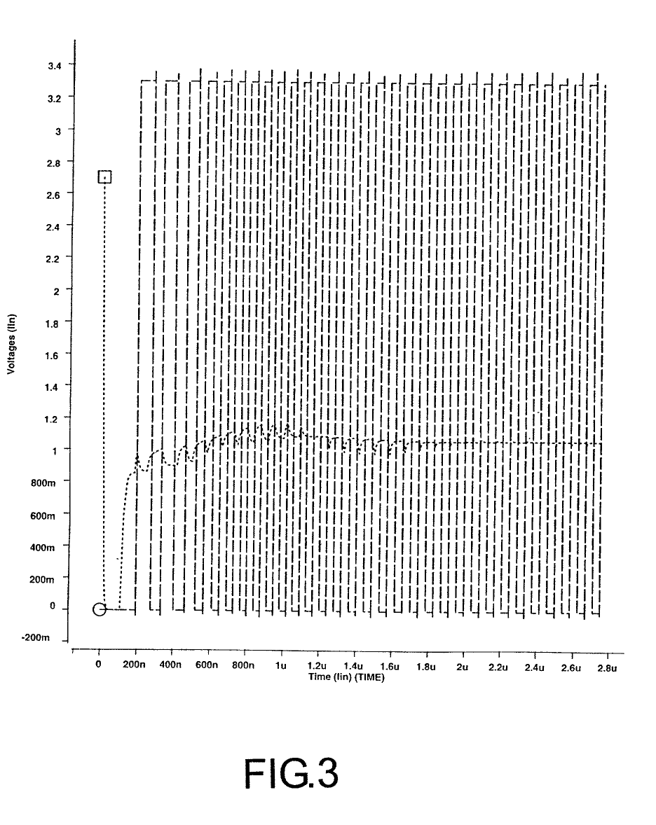

FIG. 3 shows the response oscillogram of the synchronous frequency transmitted by the voltage controlled oscillator (10) in the self-adjusting oscillator (100) of the present invention, wherein, an abscissa (T) is the time axis and an axis of ordinates (V) is the voltage axis. It is obvious to see that the frequency adjusting signals shown in FIG. 3. The waveforms of the frequency presents in a steady status during a short period of time; that means, the present invention of the self-adjusting oscillator (100) adopts the efficiency generated by the synchronous frequency of a non-quartz oscillation to effectively lower down the noise in the signals and, differently from the conventional non-quartz oscillator, lower the cost of circuit design and reduce the circuits so as to facilitate industrial utilization. In addition, the generation of the synchronous frequency of the feedback closed loop is able to obtain a more precise and steadier synchronous frequency and that is an outstanding invention with industrial utilization value.

1. A self-adjusting oscillator for a universal-serial-bus (USB) connectivity interface comprising:
at least a voltage controlled oscillator for generating a USB synchronously oscillating signal to a USB electronics circuit; the synchronous frequency in the USB synchronously oscillating signal is used as the base frequency for the circuit in the USB electronic equipment;
at least a frequency feedback calculating and adjusting unit connects with a USB connectivity interface for capturing synchronous signals of the USB D+ data line and D− data line, receiving the synchronous frequency feedback generated by the voltage controlled oscillator; calculating and determining the ratio value between the captured synchronous signals of a USB D+ data line and D− data line and the synchronous frequency feedback from the voltage controlled oscillator; based on the determined result of the ratio value, a frequency adjusting signal is transmitted to the voltage controlled oscillator to relatively adjust the speed of the synchronous frequency generated by the voltage controlled oscillator.

2. The self-adjusting oscillator for a universal-serial-bus (USB) connectivity interface according to claim 1, wherein the frequency feedback calculating and adjusting unit is a micro-integrated circuit.
